(19) United States
(12) Patent Application Publication
(10) Pub. No.: US 2025/0189472 A1
(43) Pub. Date: Jun. 12, 2025

(54) DEVICE FOR DETECTING SWITCH DAMAGE USING TEMPERATURE SENSING AND METHOD OF OPERATING THE SAME

(71) Applicant: SAMSUNG ELECTRONICS CO., LTD., Suwon-si (KR)

(72) Inventor: Heeseok Han, Suwon-si (KR)

(73) Assignee: SAMSUNG ELECTRONICS CO., LTD., Suwon-si (KR)

(21) Appl. No.: 18/966,946

(22) Filed: Dec. 3, 2024

(30) Foreign Application Priority Data
Dec. 6, 2023 (KR) 10-2023-0175446

(51) Int. Cl. G01N 25/72; H03K 17/08; H03K 17/0812

(52) U.S. Cl. CPC G01N 25/72; H03K 17/08122; H03K 2017/0806

(57) ABSTRACT

Provided is a method of operating a device for detecting a damage to a switch included in a power management integrated circuit, the method including: measuring a first temperature of a switch included in a power management integrated circuit; detecting an input voltage applied to the switch; measuring a second temperature of the switch based on the detected input voltage being a power supply voltage; obtaining a first temperature change amount of the switch, based on the first temperature and the second temperature; comparing the first temperature change amount with a threshold temperature change amount; and selectively turning off the switch based on a result of the comparing.

### CROSS-REFERENCE TO RELATED APPLICATION

This application is based on and claims priority under 35 U.S.C. § 119 to Korean Patent Application No. 10-2023-0175446, filed on Dec. 6, 2023, in the Korean Intellectual Property Office, the disclosure of which is herein incorporated by reference in its entirety.

### BACKGROUND

One or more example embodiments of the disclosure relate to a method and a device for detecting a damage to a switch of a circuit that manages power and a method of operating the same.

An electronic device may include a power management integrated circuit (PMIC) for supplying appropriate power to a circuit included in the electronic device. When a switch of the PMIC is damaged and leakage current flows through the switch, overheating and fire may occur in the electronic device. Accordingly, a method of detecting a damage to the switch of the PMIC is required.

### SUMMARY

One or more example embodiments of the disclosure provide a method and a device for detecting a damage to a switch in a circuit that manages power.

According to an aspect of an example embodiment of the disclosure, there is provided a method of operating a device for detecting a damage to a switch included in a power management integrated circuit, the method including: measuring a first temperature of a switch included in a power management integrated circuit; detecting an input voltage applied to the switch; measuring a second temperature of the switch based on the detected input voltage being a power supply voltage; obtaining a first temperature change amount of the switch, based on the first temperature and the second temperature; comparing the first temperature change amount with a threshold temperature change amount; and selectively turning off the switch based on a result of the comparing.

According to an aspect of an example embodiment of the disclosure, there is provided a device for detecting a damage to a switch of a power management integrated circuit, the device including: a temperature sensor configured to measure a first temperature of a switch; a voltage detector configured to detect an input voltage applied to the switch; and a control circuit, wherein the temperature sensor is further configured to measure a second temperature of the switch based on the detected input voltage being a power supply voltage, and wherein the control circuit is configured to: obtain a first temperature change amount of the switch, based on the first temperature and the second temperature; compare the first temperature change amount with a threshold temperature change amount; and selectively turn off the switch based on a result of the comparing.

According to an aspect of an example embodiment of the disclosure, there is provided a method of operating a power management integrated circuit including a first switch and a second switch, the method including: measuring a first temperature of at least one switch from among the first switch and the second switch; detecting an input voltage applied to the at least one switch; measuring a second temperature of the at least one switch based on the detected input voltage being a power supply voltage; obtaining a temperature change amount of the at least one switch, based on the first temperature and the second temperature; comparing the temperature change amount with a threshold temperature change amount; and selectively turning off the at least one switch based on a result of the comparing, wherein the first switch is a high side switch, and the second switch is a low side switch.

### BRIEF DESCRIPTION OF DRAWINGS

Example embodiments will be more clearly understood from the following detailed description taken in conjunction with the accompanying drawings in which:

FIG. 1 is a block diagram showing a power management integrated circuit (PMIC) and a load according to one or more example embodiments;

FIG. 2 is a block diagram showing a damage detector according to one or more example embodiments;

FIG. 3 is a block diagram showing a PMIC including one or more switches according to one or more example embodiments;

FIG. 4 is a circuit diagram showing a switch of a PMIC according to one or more example embodiments;

FIG. 5A is a flowchart of a method of operating a damage detector, according to one or more example embodiments;

FIG. 5B is a flowchart of a repetitive operation of a damage detector according to one or more example embodiments;

FIG. 6 is a flowchart of a method of operating a PMIC, according to one or more example embodiments;

FIG. 7 is a flowchart of a method of operating a PMIC including one or more switches, according to one or more example embodiments;

FIG. 8 is a block diagram showing a PMIC including a damage detector that performs temperature sensing and current sensing according to one or more example embodiments;

FIG. 9 is a diagram of a system to which a storage device according to one or more example embodiments is applied;

FIG. 10 is a diagram of a universal flash storage (UFS) system according to one or more example embodiments; and

FIG. 11 is a block diagram of a wireless communication device according to one or more example embodiments.

### DETAILED DESCRIPTION

Hereinafter, example embodiments are described with reference to the accompanying drawings.

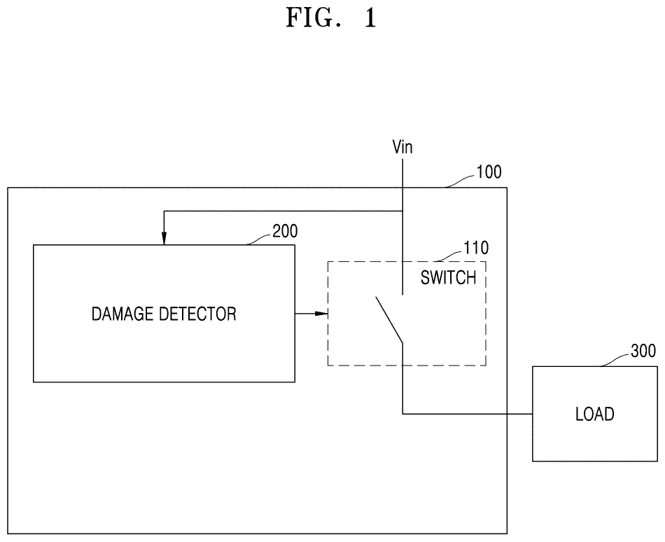

FIG. 1 is a block diagram showing a power management integrated circuit (PMIC) and a load according to one or more example embodiments.

Referring to FIG. 1, a PMIC 100 includes a damage detector 200 and a switch 110. The PMIC 100 may provide an appropriate voltage and an appropriate current to a load 300. For example, the PMIC 100 may convert an alternating current into a direct current, convert high pressure into low pressure, and/or distribute a current. The PMIC 100 may further include components for providing an appropriate voltage and current to the load 300. The PMIC 100 may receive a power supply voltage under the control by a host, generate a voltage, and provide the voltage to the load 300.

The PMIC 100 includes the damage detector 200 and the switch 110. The switch 110 may be turned on or turned off. According to one or more embodiments, when the switch 110 is turned on, the PMIC 100 may provide a voltage to the load 300, and when the switch 110 is turned off, the PMIC 100 may not provide a voltage to the load 300.

According to one or more embodiments, the damage detector 200 may measure a first temperature of the switch 110. The first temperature may be an initial temperature of the switch 110, which is a temperature of the switch 110 before the power supply voltage is applied to the switch 110. The damage detector 200 may detect an input voltage Vin applied to the switch 110. According to one or more embodiments, the damage detector 200 may measure the first temperature of the switch 110 before detecting the input voltage Vin. The damage detector 200 may measure a second temperature of the switch 110 when the input voltage Vin is greater than or equal to the power supply voltage. For example, when the input voltage Vin is the power supply voltage, the damage detector 200 may measure the second temperature of the switch 110. The power supply voltage may be VDD. The second temperature may be a temperature of the switch 110 when the power supply voltage is applied to the switch 110. The damage detector 200 may re-measure (e.g., periodically) the first temperature when the input voltage Vin is less than the power supply voltage. The damage detector 200 may obtain a first temperature change amount of the switch 110, based on the first temperature (e.g., initially measured or re-measured) and the second temperature. The damage detector 200 may compare the first temperature change amount with a threshold temperature change amount.

The damage detector 200 may turn off the switch 110 based on the comparison result between the first temperature change amount and the threshold temperature change amount. For example, when the first temperature change amount is greater than the threshold temperature change amount, the damage detector 200 may turn off the switch 110. As a result, the damaged switch 110 may not be turned on, thereby protecting the PMIC 100. In addition, when the first temperature change amount is less than or equal to the threshold temperature change amount, the damage detector 200 may control the switch 110 to operate normally.

The damage detector 200 may repeatedly check if there is a damage to the switch 110 by periodically sensing the input voltage Vin applied to the switch 110. For example, the damage detector 200 may measure a third temperature of the switch 110 when the power supply voltage is detected as being applied to the switch 110 after controlling the switch 110 to operate normally (that is, after measuring the first temperature and the second temperature and controlling the switch 110 to operate normally based thereon). The third temperature may be a temperature of the switch 110 when the power supply voltage is applied to the switch 110. The damage detector 200 may calculate a second temperature change amount of the switch 110, based on the first temperature and the third temperature. The damage detector 200 may compare the second temperature change amount with a threshold temperature change amount. The damage detector 200 may turn off the switch 110 when the second temperature change amount is greater than the threshold temperature change amount.

According to one or more embodiments, the first temperature change amount may be the difference between the second temperature and the first temperature. According to another embodiment, the first temperature change amount may be a ratio of the second temperature to the first temperature. However, these are merely examples and the embodiments are not limited thereto.

As described above, the damage detector 200 According to one or more embodiments may detect whether the switch 110 is damaged before the damaged switch 110 of the PMIC 100 is in operation.

The damage detector 200 According to one or more embodiments may detect whether the switch 110 is damaged without sensing a leakage current of the switch 110 of the PMIC 100.

The damage detector 200 According to one or more embodiments may detect a damage to the switch 110 by detecting a temperature change of the switch 110 of the PMIC 100.

The damage detector 200 According to one or more embodiments may detect a damage to the switch 110 even when the leakage current of the switch 110 is very small by detecting the temperature change of the switch 110 depending on whether the power supply voltage is applied to the switch 110 of the PMIC 100.

The PMIC 100 According to one or more embodiments may independently detect whether the switch 110 of the PMIC 100 is damaged by detecting a temperature change of the PMIC 100.

The PMIC 100 According to one or more embodiments may be included in various electronic devices. For example, the PMIC 100 may be included in a storage device that includes at least one of a volatile memory, such as a dynamic random-access memory (DRAM), a static random-access memory (SRAM), etc., and a non-volatile memory (NVM) and may also be included in a wireless communication device.

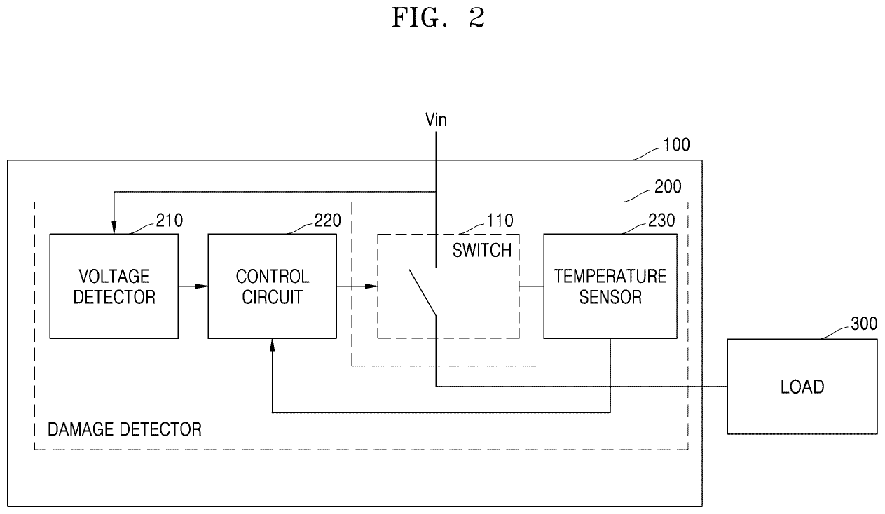

FIG. 2 is a block diagram showing a damage detector according to one or more example embodiments. FIG. 2 may be described with reference to FIG. 1, and repeated descriptions may be omitted.

Referring to FIG. 2, a PMIC 100 includes a damage detector 200, and a switch 110.

The damage detector 200 may include a voltage detector 210, a control circuit 220, and a temperature sensor 230.

According to one or more embodiments, the damage detector 200 may include the temperature sensor 230 that measures the temperature of the switch 110, the voltage detector 210 that detects the input voltage Vin applied to the switch 110, and the control circuit 220. The temperature sensor 230 may periodically measure the temperature of the switch 110 and may transmit the measured temperature value to the control circuit 220. The voltage detector 210 may periodically detect the input voltage Vin that is applied to the switch 110 and may transmit the magnitude of the input voltage Vin to the control circuit 220.

The control circuit 220 may measure a first temperature of the switch 110 through the temperature sensor 230. The first temperature may be an initial temperature of the switch 110, which is a temperature of the switch 110 before a power supply voltage is applied to the switch 110. The control circuit 220 may measure a second temperature of the switch 110 through the temperature sensor 230 when the input voltage Vin is greater than or equal to the power supply voltage. For example, when the input voltage Vin is the power supply voltage, the control circuit 220 may measure the second temperature of the switch 110 through the temperature sensor 230. When the input voltage Vin of the control circuit 220 is less than the power supply voltage of the switch 110, the control circuit 220 may re-measure or re-sense (e.g., periodically) the first temperature of the switch 110 through the temperature sensor 230.

The control circuit 220 may calculate a first temperature change amount of the switch 110, based on the first temperature and the second temperature. The control circuit 220 may compare the first temperature change amount with a threshold temperature change amount. The control circuit 220 may turn off the switch 110 based on the comparison result between the first temperature change amount and the threshold temperature change amount. The control circuit 220 may control the switch 110 to be turned off when the first temperature change amount is greater than the threshold temperature change amount. The control circuit 220 may control the switch 110 to operate normally when the first temperature change amount is less than or equal to the threshold temperature change amount. For example, the switch 110 may be periodically and/or repeatedly turned on and turned off.

According to one or more embodiments, after the control circuit 220 measures the first temperature of the switch 110 through the temperature sensor 230, the control circuit 220 may detect the power supply voltage applied to the switch 110 through the voltage detector 210.

The control circuit 220 may repeatedly check if there is a damage to the switch 110 by repeating the operations described above. For example, the control circuit 220 may repeatedly check if there is a damage to the switch 110 by periodically sensing the input voltage Vin that is applied to the switch 110. According to one or more embodiments, after controlling the switch 110 to operate normally, the control circuit 220 may measure a third temperature of the switch 110 through the temperature sensor 230 when the power supply voltage is detected as being applied to the switch 110. The control circuit 220 may calculate a second temperature change amount of the switch 110, based on the first temperature and the third temperature. The control circuit 220 may compare the second temperature change amount with a threshold temperature change amount. The control circuit 220 may turn off the switch 110 when the second temperature change amount is greater than the threshold temperature change amount.

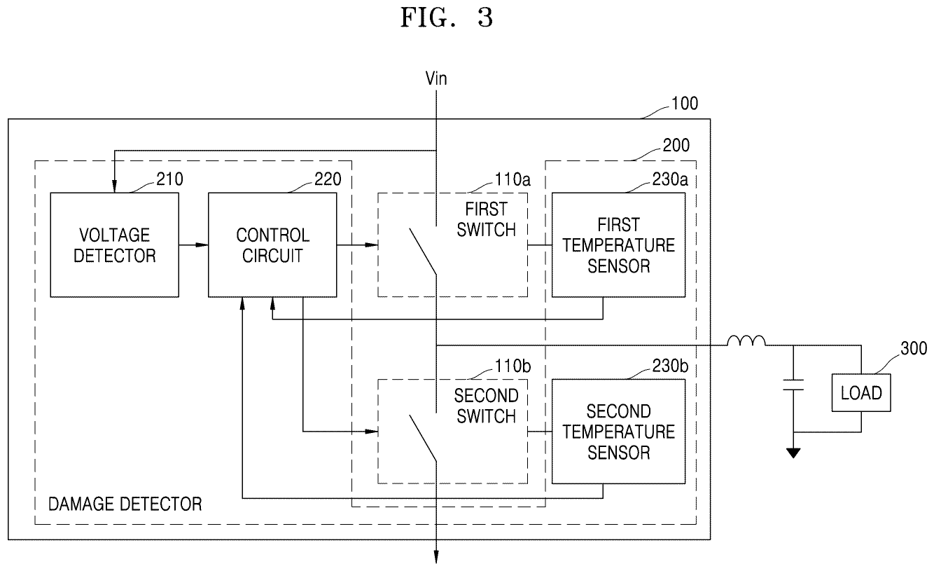

FIG. 3 is a block diagram showing a PMIC including one or more switches according to one or more example embodiments.

Referring to FIG. 3, a PMIC 100 may include a damage detector 200, a first switch 110a, and a second switch 110b. The PMIC 100 may periodically turn on and turn off each of the first switch 110a and the second switch 110b and may provide a voltage less than an input voltage Vin to a load 300.

The damage detector 200 may include a voltage detector 210, a control circuit 220, a first temperature sensor 230a, and a second temperature sensor 230b. The first temperature sensor 230a may periodically sense a temperature of the first switch 110a and transmit temperature information of the first switch 110a to the control circuit 220. The second temperature sensor 230b may periodically sense a temperature of the second switch 110b and transmit temperature information of the second switch 110b to the control circuit 220.

According to one or more embodiments, the control circuit 220 may measure a first temperature of at least one switch from among the first switch 110a and the second switch 110b. The first temperature may be an initial temperature of the at least one switch from among the first switch 110a and the second switch 110b. The first temperature may be measured before a power supply voltage is applied to the first switch 110a or the second switch 110b. The control circuit 220 may detect the input voltage Vin applied to the first switch 110a. When the input voltage Vin is greater than or equal to the power supply voltage, the control circuit 220 may measure a second temperature of the at least one switch. The control circuit 220 may re-measure (e.g., periodically) the first temperature of the at least one switch when the input voltage Vin is less than the power supply voltage.

The control circuit 220 may generate a temperature change amount of the at least one switch, based on the first temperature and the second temperature thereof. The control circuit 220 may compare the temperature change amount with a threshold temperature change amount. The control circuit 220 may turn off the corresponding at least one switch based on the comparison result between the temperature change amount of the corresponding at least one switch and the threshold temperature change amount. For example, the control circuit 220 may turn off the corresponding at least one switch when the temperature change amount of the corresponding at least switch is greater than the threshold temperature change amount. The control circuit 220 may control the corresponding at least one switch to operate normally when the temperature change amount of the corresponding at least switch is less than or equal to the threshold temperature change amount.

The first switch 110a may be a high side switch, and the second switch 110b may be a low side switch. The high side switch may refer to a switch that receives the input voltage, and the low side switch may refer to a switch connected to ground. In other words, the low side switch may be referred to as a grounded switch.

According to one or more embodiments, the damage detector 200 may detect whether at least one of the first switch 110a and the second switch 110b is damaged based on whether the power supply voltage is applied to the first switch 110a. Specifically, when the power supply voltage is applied to the first switch 110a, the damage detector 200 may sense the temperature of the first switch 110a through the first temperature sensor 230a and may sense the temperature of the second switch 110b through the second temperature sensor 230b. When the temperature change amount of the first switch 110a is greater than the threshold temperature change amount, the damage detector 200 may turn off the first switch 110a. When the temperature change amount of the second switch 110b is greater than the threshold temperature change amount, the damage detector 200 may turn off the second switch 110b.

As described above, the damage detector 200 according to one or more embodiments may detect the power supply voltage applied to one switch from among one or more switches included in the PMIC 100 and may detect whether one or more switches are damaged by detecting the temperature change of the one or more switches according to the power supply voltage.

The PMIC 100 may include a variety of switches, and even when the PMIC 100 includes various switches, a damage to any one of the switches may be detected as described above.

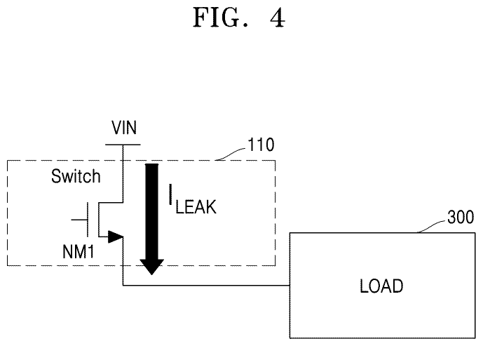

FIG. 4 is a circuit diagram showing a switch of a PMIC according to one or more example embodiments. FIG. 4 may be described with reference to FIGS. 1 and 2.

Referring to FIG. 4, the switch 110 may be a metal oxide semiconductor field effect transistor (MOSFET). For example, the switch 110 may be an N-type metal oxide semiconductor (NMOS) transistor NM1. As the input voltage Vin is applied to a drain terminal of the switch 110, a leakage current ILEAK may flow into the switch 110 when the switch 110 is damaged. The damage detector 200 according to one or more embodiments may determine whether the switch is damaged by detecting the power supply voltage applied to the switch 110 without sensing the leakage current ILEAK and detecting a temperature change of the switch 110.

The damage detector 200 may control the switch 110 not to operate. For example, the damage detector 200 may control the switch 110 not to operate based on detection of a damage to the switch 110. For example, the damage detector 200 may transmit a signal for a protection mode to the switch 110. As an example, the damage detector 200 may not apply a voltage, at which the transistor NM1 is turned on, to a gate terminal of the transistor NM1.

The damage detector 200 may control the switch 110 to operate normally. For example, the damage detector 200 may control the switch 110 to operate normally based on a damage to the switch 110 not being detected. For example, the damage detector 200 may transmit a signal for a normal mode to the switch 110. For example, the damage detector 200 may apply a voltage, at which the transistor NM1 is turned on, to the gate terminal of the transistor NM1.

Unlike FIG. 4, in another embodiment, the switch 110 may be a P-type metal oxide semiconductor (PMOS) transistor.

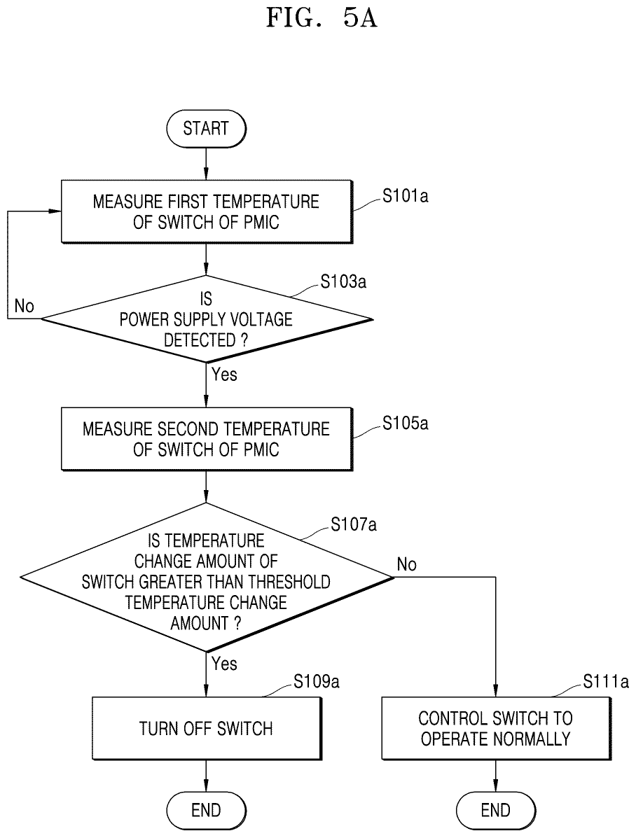

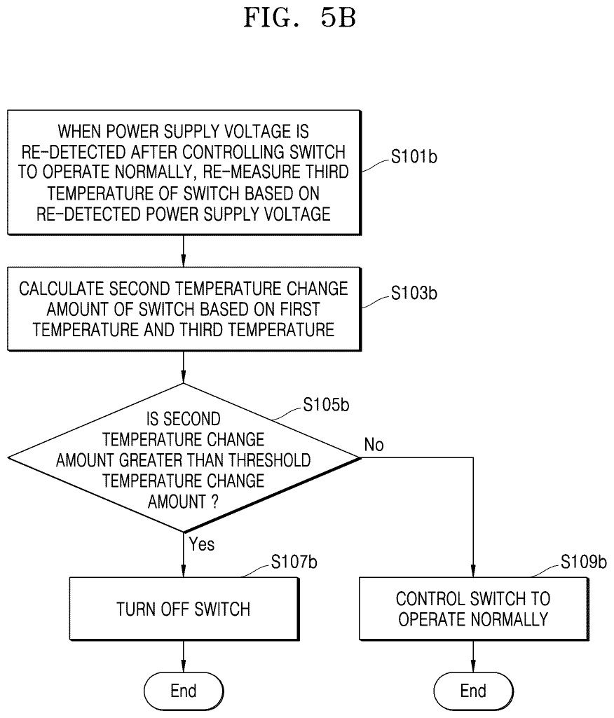

FIG. 5A is a flowchart of a method of operating a damage detector, according to one or more example embodiments. FIG. 5A may be described with reference to FIGS. 1 and 2.

Referring to FIG. 5A, in operation S101a, the damage detector 200 measures the first temperature of the switch 110 of the PMIC 100.

In operation S103a, the damage detector 200 may detect the input voltage Vin applied to the switch 110. When the input voltage Vin is greater than or equal to the power supply voltage, the damage detector 200 may detect the power supply voltage through the voltage detector 210. When the damage detector 200 does not detect the power supply voltage, the first temperature of the switch 110 may be re-measured by returning to operation S101a.

In operation S105a, when the damage detector 200 detects the power supply voltage, the damage detector 200 may measure the second temperature of the switch 110 of the PMIC 100.

In operation S107a, the damage detector 200 may compare the temperature change amount of the switch 110 with the threshold temperature change amount.

In operation S109a, when the temperature change amount of the switch 110 is greater than the threshold temperature change amount, the damage detector 200 may turn off the switch 110. As a result, the damaged switch 110 may not be turned on, thereby protecting the PMIC 100.

In operation S111a, when the temperature change amount of the switch 110 is less than or equal to the threshold temperature change amount, the damage detector 200 may control the switch 110 to operate normally.

FIG. 5B is a flowchart of a repetitive operation of a damage detector according to one or more example embodiments. FIG. 5B may be described with reference to FIGS. 1, 2, and 5A.

Referring to FIG. 5B, in operation S101b, when the power supply voltage is re-detected after controlling the switch 110 to operate normally, the damage detector 200 may re-measure the third temperature of the switch 110 based on the re-detected power supply voltage.

In operation S103b, the damage detector 200 may calculate the second temperature change amount of the switch 110, based on the first temperature and the third temperature.

In operation S105b, the damage detector 200 may compare the second temperature change amount with the threshold temperature change amount.

In operation S107b, when the second temperature change amount is greater than the threshold temperature change amount, the damage detector 200 may turn off the switch 110.

In operation S109b, when the second temperature change amount is less than or equal to the threshold temperature change amount, the damage detector 200 may control the switch 110 to operate normally.

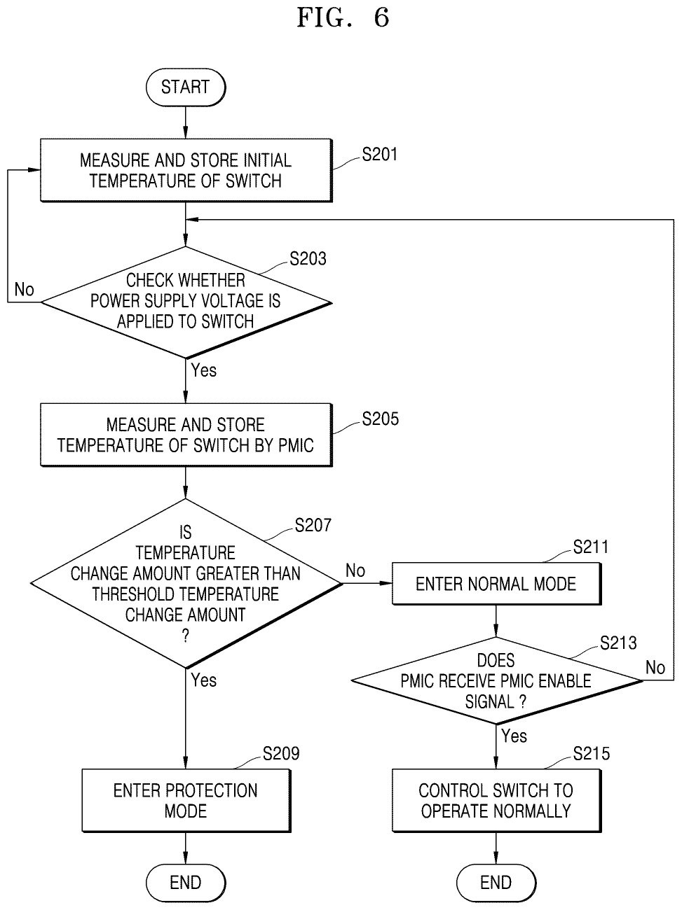

FIG. 6 is a flowchart of a method of operating a PMIC, according to one or more example embodiments. FIG. 6 may be described with reference to FIG. 1.

Referring to FIG. 6, in operation S201, the PMIC 100 (e.g., using the temperature sensor 230 in FIG. 2) may measure and store the initial temperature (or the first temperature) of the switch 110.

In operation S203, the PMIC 100 (e.g., using the voltage detector 210 in FIG. 2) may check whether the power supply voltage is applied to the switch 110. When the power supply voltage is not applied to the switch 110, the PMIC 100 may measure and store the initial temperature of the switch 110 by returning to operation S201.

In operation S205, when the power supply voltage is applied to the switch 110, the PMIC 100 may measure and store the second temperature of the switch 110.

In operation S207, the PMIC 100 may compare the threshold temperature change amount with a value obtained by subtracting the first temperature from the second temperature.

In operation S209, when the value obtained by subtracting the first temperature from the second temperature is greater than the threshold temperature change amount, the PMIC 100 may enter the protection mode. The protection mode may refer to a mode in which the damaged switch 110 is not turned on.

In operation S211, when the value obtained by subtracting the first temperature from the second temperature is less than or equal to the threshold temperature change amount, the PMIC 100 may enter the normal mode. The normal mode may refer to a mode in which the switch 110 is normally turned on and turned off.

In operation S213, the PMIC 100 may determine whether a PMIC enable signal is received. When the PMIC 100 does not receive the PMIC enable signal within a specific time period (‘No’ at operation S213), the PMIC 100 may re-check whether the power supply voltage is applied to the switch 110 by returning to operation S203.

In operation S215, when the PMIC 100 receives the PMIC enable signal (‘Yes’ at operation S213), the switch 110 may operate normally.

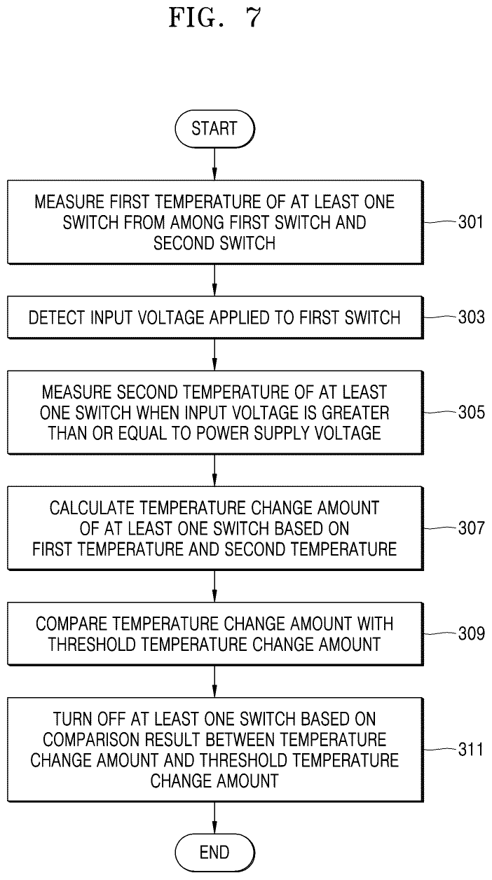

FIG. 7 is a flowchart of a method of operating a PMIC including one or more switches, according to one or more example embodiments. FIG. 7 may be described with reference to FIGS. 1 and 2.

Referring to FIG. 7, in operation 301, the PMIC 100 may measure the first temperature of at least one switch from among the first switch 110a and the second switch 110b.

In operation 303, the PMIC 100 may detect the input voltage Vin applied to the first switch 110a.

In operation 305, the PMIC 100 may measure the second temperature of the at least one switch when the input voltage Vin is greater than or equal to the power supply voltage. When the input voltage Vin is less than the power supply voltage, the PMIC 100 may re-measure (e.g., periodically) the first temperature of the at least one switch.

In operation 307, the PMIC 100 may calculate the temperature change amount of the at least one switch, based on the first temperature and the second temperature.

In operation 309, the PMIC 100 may compare the temperature change amount with the threshold temperature change amount.

In operation 311, the PMIC 100 may turn off the at least one switch based on the comparison result between the temperature change amount of the corresponding at least switch and the threshold temperature change amount. For example, when the temperature change amount of the corresponding at least switch is greater than the threshold temperature change amount, the PMIC 100 may turn off the corresponding at least one switch. In addition, when the temperature change amount of the corresponding at least switch is less than or equal to the threshold temperature change amount, the PMIC 100 may control the corresponding at least one switch to operate normally.

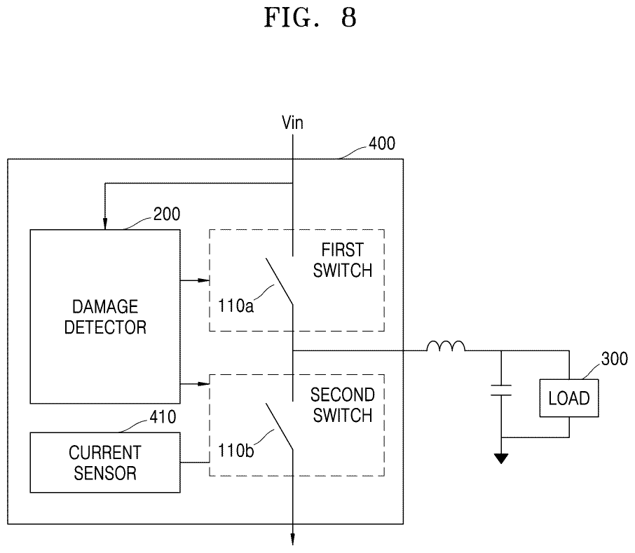

FIG. 8 is a block diagram showing a PMIC including a damage detector that performs temperature sensing and current sensing according to one or more example embodiments.

Referring to FIG. 8, a PMIC 400 according to one or more embodiments may include a damage detector 200, a first switch 110a, a second switch 110b, and a current sensor 410. The first switch 110a may be a high side switch, and the second switch 110b may be a low side switch. The high side switch may refer to a switch that receives the input voltage Vin, and the low side switch may refer to a switch connected to ground. In other words, the low side switch may be referred to as a grounded switch.

When the power supply voltage is applied to the first turning switch 110a, the PMIC 400 may determine whether the first switch 110a is damaged based on the temperature change amount of the first switch 110a.

The current sensor 410 of the PMIC 400 may determine whether the second switch 110b is damaged by sensing a leakage current flowing through the second switch 110b. In addition or alternatively, when the power supply voltage is applied to the first switch 110a, the PMIC 400 may determine whether the second switch 110b is damaged based on the temperature change amount of the second switch 110b.

In other words, as described above, the PMIC 400 according to one or more embodiments may detect a damage to the high side switch by sensing the temperature of the high side switch and may detect a damage to the low side switch by sensing at least one of the temperature of the low side switch and the current flowing through the low side switch.

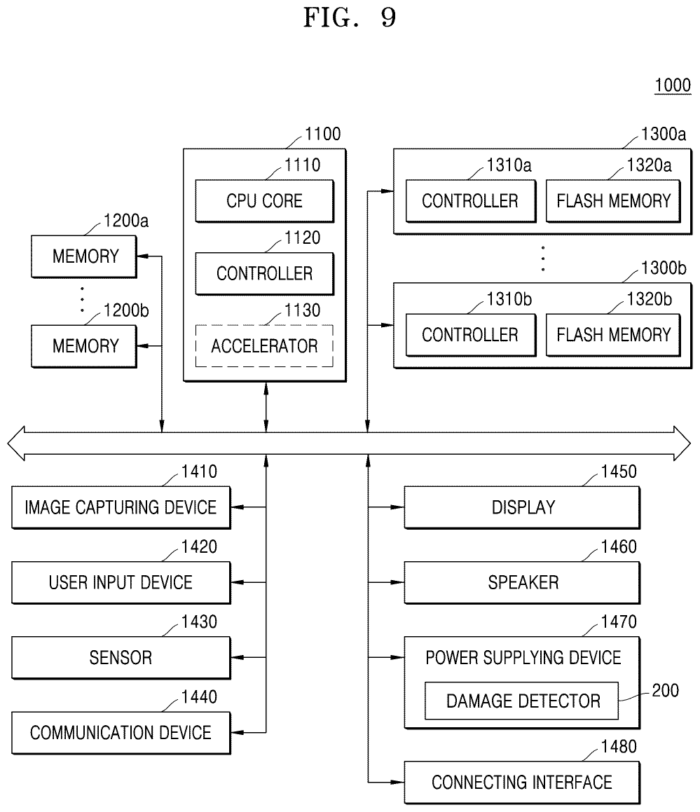

FIG. 9 is a diagram of a system to which a storage device according to one or more example embodiments is applied. FIG. 9 may be described with reference to FIGS. 1 and 2.

Referring to FIG. 9, a diagram of a system 1000 to which a storage device according to one or more embodiments is applied is shown. The system 1000 of FIG. 9 may basically be a mobile system, such as a mobile phone, a smartphone, a tablet personal computer, a wearable device, a healthcare device, and/or an Internet of things (IoT) device, but is not necessarily limited thereto. The system 1000 of FIG. 9 may also include a personal computer, a laptop computer, a server, a media player, and/or an automotive device such as navigation.

Referring to FIG. 9, the system 1000 may include a main processor 1100, memories 1200a and 1200b, and storage devices 1300a and 1300b and may further include one or more of an image capturing device 1410, a user input device 1420, a sensor 1430, a communication device 1440, a display 1450, a speaker 1460, a power supplying device 1470, and a connecting interface 1480.

The main processor 1100 may control the overall operation of the system 1000, and more specifically, the operation of other components constituting the system 1000. The main processor 1100 may be implemented as a general-purpose processor, a microprocessor, a microcontroller, a dedicated processor, and/or an application processor.

The main processor 1100 may include one or more CPU cores 1110 and may further include a controller 1120 to control the memories 1200a and 1200b and/or the storage devices 1300a and 1300b. According to one or more embodiments, the main processor 1100 may further include an accelerator 1130, which is a dedicated circuit for high-speed data computation, such as artificial intelligence (AI) data computation. The accelerator 1130 may include a graphics processing unit (GPU), a neutral processing unit (NPU) and/or a data processing unit (DPU) and may also be implemented as a separate chip that is physically independent from other components of the main processor 1100.

The memories 1200a and 1200b may be used as primary memory of the system 1000 and may include a volatile memory such as an SRAM and/or a DRAM but may also include NVM, such as a flash memory, a phase-change random-access memory (PRAM) and/or a resistive random-access memory (RRAM). The memories 1200a and 1200b may also be implemented within the same package as the main processor 1100.

The storage devices 1300a and 1300b may function as a non-volatile storage device that stores data regardless of whether power is supplied and may have a relatively large storage capacity compared to the memories 1200a and 1200b. The storage devices 1300a and 1300b may include storage controllers 1310a and 1310b and flash memories 1320a and 1320b that store data under the control by the storage controllers 1310a and 1310b. The NVMs 1320a and 1320b may include flash memory in a two-dimensional (2D) structure or a three-dimensional (3D) vertical NAND (V-NAND) structure but may also include other types of an NVM, such as a PRAM and/or an RRAM.

The storage devices 1300a and 1300b may be included in the system 1000 while being physically separated from the main processor 1100 or may be implemented in the same package as the main processor 1100. In addition, the storage devices 1300a and 1300b may be in the same form as a solid state device SSD or a memory card and may be detachably coupled to other components of the system 1000 through an interface, such as the connecting interface 1480, to be described below. The storage devices 1300a and 1300b may be, but are not necessarily limited to, devices to which standard protocols, such as universal flash storage (UFS), embedded multi-media card (eMMC), and/or non-volatile memory express (NVMe), are applied.

The image capturing device 1410 may capture still images and/or moving images and may include a camera, a camcorder, and/or a webcam.

The user input device 1420 may receive various types of data input from users of the system 1000 and may include a touchpad, a keypad, a keyboard, a mouse, and/or a microphone.

The sensor 1430 may detect various types of physical quantities that may be obtained from the outside of the system 1000 and may convert the detected physical quantities into electrical signals. The sensor 1430 may include a temperature sensor, a pressure sensor, an illumination sensor, a position sensor, an acceleration sensor, a biosensor, and/or a gyroscope sensor.

The communication device 1440 may exchange signals with other devices outside the system 1000 according to various communication protocols. The communication device 1440 may be implemented including an antenna, a transmitter, and/or a MODEM.

The display 1450 and the speaker 1460 may function as output devices that output visual information and audio information to users of the system 1000, respectively.

The power supplying device 1470 may appropriately convert power supplied from a battery (not shown) built into the system 1000 and/or an external power source and supply the converted power to each component of the system 1000. The power supplying device 1470 may include the damage detector 200 According to one or more embodiments. The damage detector 200 may detect a damage to any one of switches of the power supplying device 1470.

The connecting interface 1480 may provide a connection between the system 1000 and an external device that is connected to the system 1000 and is capable of exchanging data with the system 1000. The connecting interface 1480 may be implemented in various interface formats, such as advanced technology attachment (ATA), serial ATA (SATA), external SATA (e-SATA), small computer small interface (SCSI), serial attached SCSI (SAS), a peripheral component interconnect (PCI), PCI express (PCIe), NVMe, IEEE 1394, universal serial bus (USB), secure digital (SD) card, multi-media card (MMC), eMMC, UFS, embedded universal flash storage (eUFS), and a compact flash (CF) card interface.

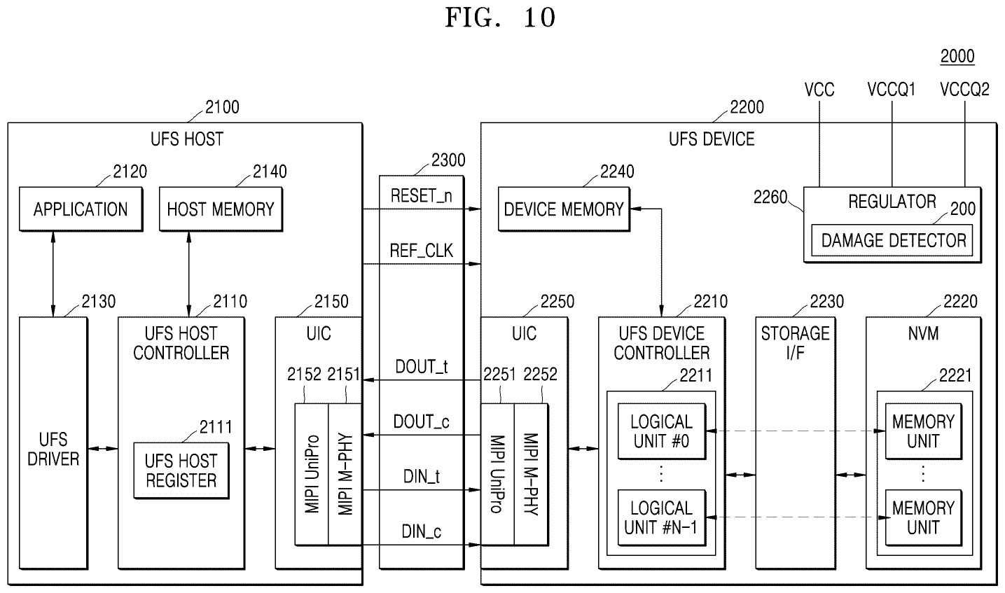

FIG. 10 is a diagram of a UFS system according to one or more example embodiments. FIG. 10 may be described with reference to FIGS. 1 and 2.

Referring to FIG. 10, a diagram of a UFS system 2000 According to one or more embodiments is shown. The UFS system 2000, which may be a system that complies with the UFS standards published by the Joint Electron Device Engineering Council (JEDEC), may include a UFS host 2100, a UFS device 2200, and a UFS interface 2300. The description of the system 1000 of FIG. 9 described above may also be applied to the UFS system 2000 of FIG. 10 to the extent that it does not conflict with the following description of FIG. 10.

Referring to FIG. 10, the UFS host 2100 and the UFS device 2200 may be interconnected through the UFS interface 2300. When the main processor 1100 in FIG. 9 is an application processor, the UFS host 2100 may be implemented as a part of the application processor. A UFS host controller 2110 and host memory 2140 may correspond to the controller 1120 of the main processor 1100 and the memories 1200a and 1200b in FIG. 9, respectively. The UFS device 2200 may correspond to the storage devices 1300a and 1300b in FIG. 9, and a UFS device controller 2210 and an NVM 2220 may correspond to the storage controllers 1310a and 1310b and the NVMs 1320a and 1320b in FIG. 9 respectively.

The UFS host 2100 may include a UFS host controller 2110, an application 2120, a UFS driver 2130, host memory 2140, and a UIC layer 2150. The UFS device 2200 may include a UFS device controller 2210, an NVM 2220, a storage interface 2230, device memory 2240, a UIC layer 2250, and a regulator 2260. The NVM 2220 may include a plurality of memory units 2221. The plurality of memory units 2221 may include a V-NAND flash memory in a 2D or 3D structure but may also include other types of an NVM, such as a PRAM and/or an RRAM. The UFS device controller 2210 may be connected to the NVM 2220 through the storage interface 2230. The storage interface 2230 may be implemented to comply with standard protocols, such as toggle or ONFI (Open NAND Flash Interface).

The application 2120 may refer to a program that wishes to communicate with the UFS device 2200 to use the functions of the UFS device 2200. The application 2120 may transmit an input-output request (IOR) to the UFS driver 2130 for input and output to the UFS device 2200. The IOR may refer to a read request, a write request, and/or a discard request of data, but is not necessarily limited thereto.

The UFS driver 2130 may manage the UFS host controller 2110 through a UFS-host controller interface (HCI). The UFS driver 2130 may convert the IOR generated by the application 2120 into a UFS command defined by the UFS standard and may transmit the UFS command to the UFS host controller 2110. One IOR may be converted into a plurality of UFS commands. The UFS commands may basically be commands defined by the SCSI standard but may also be commands exclusive to the UFS standard.

The UFS host controller 2110 may transmit the UFS commands converted by the UFS driver 2130 to the UIC layer 2250 of the UFS device 2200 through the UIC layer 2150 and the UFS interface 2300. In this process, a UFS host register 2111 of the UFS host controller 2110 may function as a command queue (CQ).

The UIC layer 2150 of the UFS host 2100 may include MIPI M-PHY 2151 and MIPI UniPro 2152, and the UIC layer 2250 of the UFS device 2200 may also include MIPI M-PHY 2251 and MIPI Unipro 2252.

The UFS interface 2300 may include a line that transmits a reference clock REF_CLK, a line that transmits a hardware reset signal RESET_n to the UFS device 2200, a pair of lines that transmit a differential input signal pair DIN_t and DIN_c, and a pair of lines that transmit a differential output signal pair DOUT_t and DOUT_c.

A frequency value of the reference clock REF_CLK provided from the UFS host 2100 to the UFS device 2200 may be one of four values: 19.2 MHZ, 26 MHZ, 38.4 MHZ, and 52 MHz, but is not necessarily limited thereto. The UFS host 2100 may change the frequency value of the reference clock REF_CLK even during operation, e.g., during data transmission and reception between the UFS host 2100 and UFS device 2200. The UFS device 2200 may generate clocks of various frequencies from the reference clock REF_CLK provided from the UFS host 2100, using a phase-locked loop (PLL), etc. In addition, the UFS host 2100 may set a data rate value between the UFS host 2100 and the UFS device 2200 through the frequency value of the reference clock REF_CLK. In other words, the data rate value may be determined based on the frequency value of the reference clock REF_CLK.

The UFS interface 2300 may support multiple lanes, and each lane may be implemented as a different line pair. For example, the UFS interface 2300 may include one or more receive lanes and one or more transmit lanes. In FIG. 10, a pair of lines configured to transmit the differential input signal pair DIN_t and DIN_c may constitute the receive lane, and a pair of lines configured to transmit the differential output signal pair DOUT_t and DOUT_c may constitute the transmit lane. Although FIG. 10 shows one transmit lane and one receive lane, the number of transmit lanes and receive lanes may vary.

The receive lane and the transmit lane may transmit data through a serial communication method, and due to the structure in which the receive lane and the transmit lane are separated, full-duplex communication between the UFS host 2100 and the UFS device 2200 is possible. In other words, the UFS device 2200 may transmit data to the UFS host 2100 through the transmit lane while receiving data from the UFS host 2100 through the receive lane. In addition, control data, such as commands from the UFS host 2100 to the UFS device 2200, and user data that the UFS host 2100 intends to write to the NVM 2220 of the UFS device 2200 or to read from the NVM 2220 may be transmitted through the same lane. As such, there is no need to provide a separate lane for data transmission between the UFS host 2100 and the UFS device 2200, other than a pair of receive lanes and a pair of transmit lanes.

The UFS device controller 2210 of the UFS device 2200 may control the overall operation of the UFS device 2200. The UFS device controller 2210 may manage the NVM 2220 through logical units (LU) 2211, which are logical data storage units. The number of LUs 2211 may be eight, but is not limited thereto. The UFS device controller 2210 may include a flash translation layer FTL and may use address mapping information of the FTL to convert a logical data address, e.g., a logical block address (LBA), transmitted from the UFS host 2100, into a physical data address, e.g., a physical block address (PBA). In the UFS system 2000, a logical block for storage of the user data may have a size within a preset range. For example, the minimum size of the logic block may be set to 4 Kbytes.

When a command from the UFS host 2100 is input into the UFS device 2200 through the UIC layer 2250, the UFS device controller 2210 may perform an operation according to the input command and may transmit a completion response to the UFS host 2100 when the operation is completed.

For example, when the UFS host 2100 intends to write the user data to the UFS device 2200, the UFS host 2100 may transmit a data write command to the UFS device 2200. When a response indicating that the user data is ready to be transmitted is received from the UFS device 2200, the UFS host 2100 may transmit the user data to the UFS device 2200. The UFS device controller 2210 may temporarily write the transmitted user data to the device memory 2240 and write the user data temporarily written to the device memory 2240 to a selected location of the NVM 2220 based on the address mapping information of the FTL.

As another example, when the UFS host 2100 intends to read the user data written to the UFS device 2200, the UFS host 2200 may transmit a data read command to the UFS device 2200. The UFS device controller 2210 receiving the command may read the user data from the NVM 2220 based on the data read command and temporarily write the read user data to the device memory 2240. In this read process, the UFS device controller 2210 may detect and correct errors in the read user data, using a built-in error correction code (ECC) engine (not shown). More specifically, the ECC engine may generate parity bits for write data to be written in the NVM 2220, and the generated parity bits may be stored in the NVM 2220 together with the write data. When reading data from the NVM 2220, the ECC engine may correct errors in the read data using the parity bits read from the NVM 2220 together with the read data and may output the error-corrected read data.

In addition, the UFS device controller 2210 may transmit the user data temporarily written to the device memory 2240 to the UFS host 2100. In addition, the UFS device controller 2210 may further include an advanced encryption standard (AES) engine (not shown). The AES engine may perform at least one of encryption and decryption operations on the data which is input to the UFS device controller 2210, using a symmetric-key algorithm.

The UFS host 2100 may store commands to be transmitted to the UFS device 2200 in order in the UFS host register 2111 which may function as a CQ and may transmit the commands to the UFS device 2200 in that order. Even when the previously transmitted commands are still being processed by the UFS device 2200, that is, prior to receiving a notification that the previously transmitted commands have been processed by the UFS device 2200, the UFS host 2100 may transmit a next command waiting in the CQ to the UFS device 2200, and accordingly, the UFS device 2200 may also receive the next command from the UFS host 2100 even while processing the previously transmitted commands. The maximum number of commands that can be stored in the CQ may be, for example, 32. In addition, the CQ may be implemented as a circular queue type that indicates the start and the end of the command sequence stored in the queue through a head pointer and a tail pointer, respectively.

Each of the plurality of memory units 2221 may include a memory cell array (not shown) and a control circuit (not shown) that controls the operation of the memory cell array. The memory cell array may include a 2D memory cell array or a 3D memory cell array. The memory cell array includes multiple memory cells, and each memory cell may be a single-level cell (SLC) that stores 1 bit of information but may also be a cell that stores 2 or more bits of information, such as a multi-level cell (MLC), a triple-level cell (TLC), or a quadruple-level cell (QLC). The 3D memory cell array may include vertical NAND strings that are vertically oriented so that at least one memory cell is located on top of another memory cell.

VCC, VCCQ, VCCQ2, etc. may be input as the power supply voltage to the UFS device 2200. The VCC is a main power supply voltage for the UFS device 2200 and may have a value of about 2.4 V to about 3.6 V. The VCCQ is a power supply voltage to supply a low range voltage, mainly for the UFS device controller 2210 and may have a value of about 1.14 V to about 1.26 V. The VCCQ2 is a power supply voltage to supply a voltage in a range lower than the VCC but higher than the VCCQ, mainly for an input and output interface, such as MIPI M-PHY 2251, and may have a value of about 1.7 V to about 1.95 V. These power supply voltages may be supplied to each component of the UFS device 2200 via the regulator 2260. The regulator 2260 may be implemented as a set of unit regulators connected to the above-described power supply voltages, respectively. The regulator 2260 may include the damage detector 200 According to one or more embodiments. The damage detector 200 may detect a damage to any one of the switches of the regulator 2260.

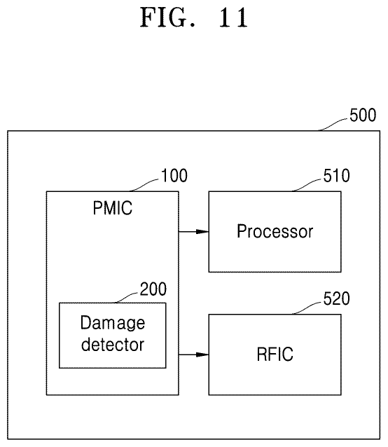

FIG. 11 is a block diagram of a wireless communication device according to one or more example embodiments. FIG. 11 may be described with reference to FIGS. 1 and 2.

Referring to FIG. 11, a wireless communication device 500 may include a PMIC 100, a processor 510, and a radio frequency integrated circuit (RFIC) 520. The wireless communication device 500 may further include components for wireless communication. The PMIC 100 includes the damage detector 200.

The PMIC 100 may provide an appropriate voltage to the processor 510 and the RFIC 520. As described above, the damage detector 200 may detect a damage to the switch 110 of the PMIC 100, and may control the switch to not operate (e.g., by entering a protection mode) based on detection of the damage to the switch 110.

While the inventive concept has been particularly shown and described with reference to example embodiments thereof, it will be understood that various changes in form and details may be made therein without departing from the spirit and scope of the following claims.

What is claimed is:

1. A method of operating a device for detecting a damage to a switch included in a power management integrated circuit, the method comprising:
measuring a first temperature of a switch included in a power management integrated circuit;
detecting an input voltage applied to the switch;
measuring a second temperature of the switch based on the detected input voltage being a power supply voltage;
obtaining a first temperature change amount of the switch, based on the first temperature and the second temperature;
comparing the first temperature change amount with a threshold temperature change amount; and
selectively turning off the switch based on a result of the comparing.

2. The method of claim 1, wherein the measuring the first temperature is performed before detecting the input voltage being the power supply voltage.

3. The method of claim 1, further comprising re-measuring the first temperature based on the detected input voltage being less than the power supply voltage.

4. The method of claim 1, wherein the selectively turning off comprises:
turning off the switch based on the first temperature change amount being greater than the threshold temperature change amount; or
controlling the switch to normally operate based on the first temperature change amount being less than or equal to the threshold temperature change amount.

5. The method of claim 4, wherein the switch is controlled to normally operate based on the first temperature change amount being less than or equal to the threshold temperature change amount, and
wherein the method further comprises, after controlling the switch to normally operate:
measuring a third temperature of the switch based on the power supply voltage applied to the switch being detected;
obtaining a second temperature change amount of the switch, based on the first temperature and the third temperature;
comparing the second temperature change amount with the threshold temperature change amount; and
selectively turning off the switch based on a result of comparing the second temperature change amount with the threshold temperature change amount.

6. The method of claim 1, wherein the obtaining the first temperature change amount comprises obtaining the first temperature change amount based on a difference between the second temperature and the first temperature.

7. The method of claim 1, wherein the obtaining the first temperature change amount comprises obtaining the first temperature change amount based on a ratio of the second temperature to the first temperature.

8. A device for detecting a damage to a switch of a power management integrated circuit, the device comprising:
a temperature sensor configured to measure a first temperature of a switch;
a voltage detector configured to detect an input voltage applied to the switch; and
a control circuit,
wherein the temperature sensor is further configured to measure a second temperature of the switch based on the detected input voltage being a power supply voltage, and
wherein the control circuit is configured to:
obtain a first temperature change amount of the switch, based on the first temperature and the second temperature;
compare the first temperature change amount with a threshold temperature change amount; and
selectively turn off the switch based on a result of the comparing.

9. The device of claim 8, wherein the first temperature is measured before the input voltage being the power supply voltage is detected by the voltage detector.

10. The device of claim 8, wherein the temperature sensor is further configured to, based on the detected input voltage being less than the power supply voltage, re-measure the first temperature.

11. The device of claim 8, wherein the control circuit is configured to:
control the switch to be turned off based on the first temperature change amount being greater than the threshold temperature change amount; or
control the switch to normally operate based on the first temperature change amount being less than or equal to the threshold temperature change amount.

12. The device of claim 11, wherein the control circuit is configured to control the switch to normally operate based on the first temperature change amount being less than or equal to the threshold temperature change amount, and
wherein the control circuit is further configured to, after controlling the switch to normally operate:
measure a third temperature of the switch through the temperature sensor based on the power supply voltage applied to the switch being detected;
obtain a second temperature change amount of the switch, based on the first temperature and the third temperature;
compare the second temperature change amount with a threshold temperature change amount; and
selectively turn off the switch based on the first temperature change amount being greater than the threshold temperature change amount.

13. The device of claim 8, wherein the control circuit is configured to obtain the first temperature change amount based on a difference between the second temperature and the first temperature.

14. The device of claim 8, wherein the control circuit is configured to obtain the first temperature change amount based on a ratio of the second temperature to the first temperature.

15. A method of operating a power management integrated circuit including a first switch and a second switch, the method comprising:
measuring a first temperature of at least one switch from among the first switch and the second switch;
detecting an input voltage applied to the first switch;
measuring a second temperature of the at least one switch based on the detected input voltage being a power supply voltage;
obtaining a temperature change amount of the at least one switch, based on the first temperature and the second temperature;
comparing the temperature change amount with a threshold temperature change amount; and
selectively turning off the at least one switch based on a result of the comparing,
wherein the first switch is a high side switch, and the second switch is a low side switch.

16. The method of claim 15, wherein the measuring of the first temperature is performed before detecting the input voltage being the power supply voltage.

17. The method of claim 15, further comprising re-measuring the first temperature based on the input voltage being less than the power supply voltage.

18. The method of claim 15, wherein the selectively turning off the at least one switch comprises:
turning off the at least one switch based on the temperature change amount being greater than the threshold temperature change amount; or
controlling the at least one switch to normally operate based on the temperature change amount being less than or equal to the threshold temperature change amount.

19. The method of claim 15, wherein the obtaining the temperature change amount comprises obtaining the temperature change amount based on a difference between the second temperature and the first temperature.

20. The method of claim 15, wherein the obtaining the temperature change amount comprises obtaining the temperature change amount based on a ratio of the second temperature to the first temperature.
